(19) United States
(12) Patent Application Publication
(10) Pub. No.: US 2014/0021332 A1
(43) Pub. Date: Jan. 23, 2014

(54) WAFER-LEVEL OPTICS MODULE AND A METHOD OF ASSEMBLING THE SAME

(71) Applicants: Yin Dong Lu, Tainan City (TW); Zhe Hao Wu, Tainan City (TW)

(72) Inventors: Yin Dong Lu, Tainan City (TW); Zhe Hao Wu, Tainan City (TW)

(73) Assignee: HIMAX TECHNOLOGIES LIMITED, Tainan City (TW)

(21) Appl. No.: 13/552,144

(22) Filed: Jul. 18, 2012

(51) Int. Cl. H01L 27/146; B32B 37/12

(52) U.S. Cl. 250/208.1; 156/292

(57) ABSTRACT

A wafer-level optics (WLO) module includes a sensor configured to convert an optical image into an electronic signal; at least one wafer-level lens; and a bracket that provides a space set on a first surface of the bracket for accommodating the sensor, and provides a second surface that is opposite to the first surface for bonding with the wafer-level lens.

### BACKGROUND OF THE INVENTION

1. Field of the Invention

The present invention generally relates to a wafer-level optics (WLO) module, and more particularly to a WLO module with a bracket.

2. Description of Related Art

Wafer-level optics (WLO) is a technique for manufacturing miniaturized optics, such as wafer-level lens, at the wafer level using semiconductor-like techniques. The WLO is widely used in camera modules of mobile devices such as mobile phones. An image sensor is another important element used in camera modules for converting an optical image passing through the wafer-level lens into an electronic signal representing a captured image.

When the wafer-level lens and the image sensor are assembled to result in a WLO module, focusing is a crucial index that determines quality of the captured image. FIG. 1 shows a cross-sectional view of a conventional assembled WLO module 100 that includes an image sensor 11 and a wafer-level lens 12. As shown in FIG. 1, the image sensor 11 is directly bonded with the wafer-level lens 12, for example, by glue. The focusing outcome of the assembled WLO module 100 may probably be affected by misalignment between the image sensor 11 and. the wafer-level lens 12.

A conventional WLO module may also be assembled. by using a threading adjustment scheme (not shown) that adjusts distance between a wafer-level lens and an image sensor by threading. Albeit more precision in focusing, the threading adjustment scheme is man-power intensive and is not capable of effective miniaturization.

For the foregoing reasons, a need has thus arisen to propose a novel WLO scheme to improve on performance such as focusing of a WLO module.

### SUMMARY OF THE INVENTION

In view of the foregoing, an embodiment of the present invention provides a wafer-level optics (WLO) module and an associated assembling method that may enable a sensor to be easily bonded with a wafer-level lens, may align, the sensor with the WLO module, or may precisely control the distance between the sensor and the wafer-level lens.

According to one embodiment, a wafer-level optics (WLO) module includes a sensor, at least one wafer-level lens and a bracket. The sensor is used to convert an optical image into an electronic signal. The bracket provides a space set on a first surface of the bracket for accommodating the sensor, and provides a second surface that is opposite to the first surface for bonding with the wafer-level lens.

### BRIEF DESCRIPTION OF THE DRAWINGS

FIG. 1 shows a cross-sectional view of a conventional assembled WLO module;

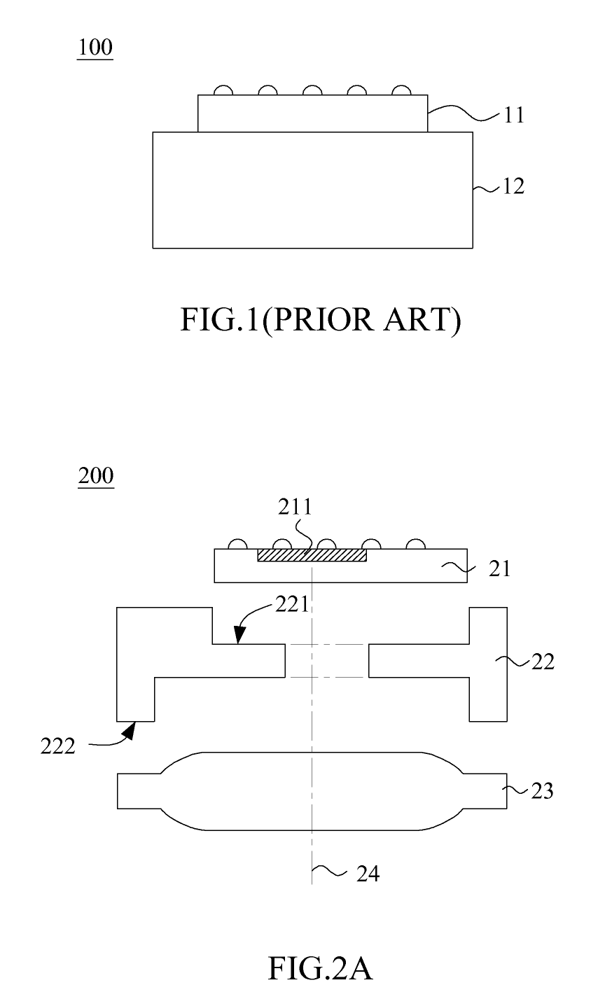

FIG. 2A shows an exploded. cross-sectional view of a WLO module according to one embodiment of the present invention;

FIG. 21B shows an assembled. cross-sectional view of the WLO module of FIG. 2A;

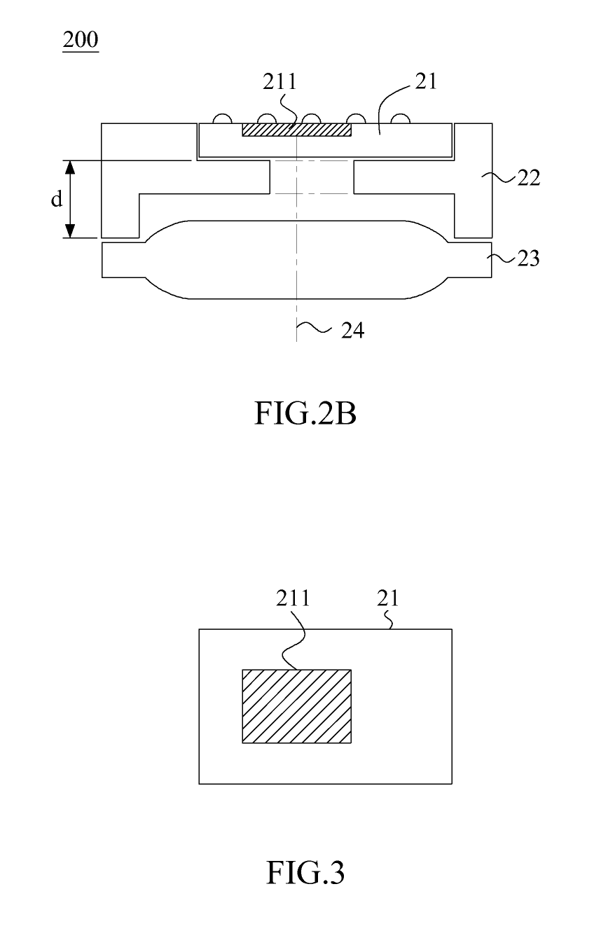

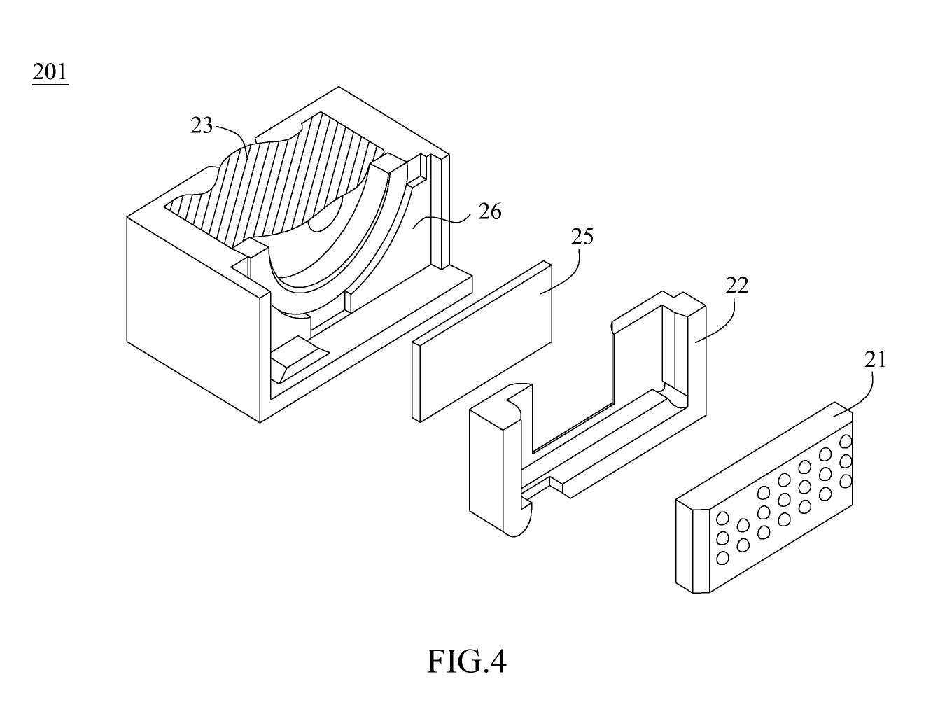

FIG. 3 schematically shows a top view of the sensor of FIG. 2A/B; and

FIG. 4 shows an exploded perspective view of another WLO module according to one embodiment of the present invention.

### DETAILED DESCRIPTION OF THE INVENTION

FIG. 2A shows an exploded cross-sectional view of a wafer-level optics (WLO) module 200 according to one embodiment of the present invention, and FIG. 2B shows an assembled cross-sectional view of the WLO module 200 of FIG. 2A. In the specification, the wafer-level optics is referred to a miniaturized optical device designed and manufactured using semiconductor-like techniques. Accordingly, the WLO module 200 may render an end product, such as a camera module for mobile devices, cost effective and may enable feasible miniaturization with reduced form factor.

In the embodiment, the WLO module 200 primarily includes a sensor 21, a bracket 22 and at least one wafer-level lens 23 (e.g., a microlens). The sensor 21 of the embodiment is an image sensor, such as a complementary metal-oxide-semiconductor (CMOS) image sensor or a charged-coupled device (CCD), which converts an optical image into an electronic signal.

The bracket 22 of the embodiment provides a space set on a first surface 221 of the bracket 22 for accommodating the sensor 21. The bracket 22 provides a second surface 222 that is opposite to the first surface 221 for bonding with the wafer-level lens 23, for example, by glue (not shown). Although a convex wafer-level lens 23 exemplified in FIGS. 2A and 2B, it is appreciated that the wafer-level lens 23 may be a concave lens, and the quantity of the wafer-level lens 23 is not limited as shown.

According to one aspect of the embodiment, as illustrated in FIG. 2A/B, the bracket 22 has a width larger than a width of the sensor 21, such that the sensor 21 may be easily bonded with the wafer-level lens 23 (which is commonly larger than the sensor 21 in size) via the bracket 22.

FIG. 3 schematically shows a top view of the sensor 21 of FIG. 2A/B. It is noted that an active array 211 of the sensor 21 may ordinarily be not located, at a center of the sensor 21. According to another aspect of the embodiment, as illustrated in FIG. 2A/B, the bracket 22 of the embodiment has an asymmetrical shape such that, when the sensor 21 is bonded with the first surface 221 of the bracket 22, a center of the active array 211 of the sensor 21 may substantially coincide with an optical axis 24 of the wafer-level lens 23 or the WLO module 200.

According to a further aspect of the embodiment, as illustrated in FIG. 2A/B, the distance d (i.e., the distance between the first surface 221 and the second surface 222) between the sensor 21 and the wafer-level lens 23 may be precisely controlled to achieve accurate focusing of the WLO module 200. Accordingly, a complicated conventional scheme such as threading adjustment between a lens and a sensor is no longer needed. In practice, a number of brackets 22 with different distances d may be manufactured and graded in advance, and a proper bracket 22 may later be selected among the graded brackets and be assembled with an associated sensor 21 and wafer-level lens 23.

FIG. 4 shows an exploded perspective view of another WLO module 201 according to one embodiment of the present invention. As shown in FIG. 4, the bracket 22 of the embodiment is indirectly, rather than directly as in FIG. 2A/B, bonded with the wafer-level lens 23. In the present embodiment, an infra-read (IR) filter 25 is interposed between the bracket 22 and the wafer-level lens 23 for blocking incoming infra-red light. Moreover, a lens barrel 26 is used in the present embodiment to hold the wafer-level lens 23.

Although specific embodiments have been illustrated and described, it will be appreciated by those skilled in the art that various modifications may be made without departing from the scope of the present invention, which is intended to he limited solely by the appended claims.

What is claimed is:

1. A wafer-level optics (WLO) module, comprising:
a sensor configured to convert an optical image into an electronic signal;
at least one wafer-level lens; and
a bracket providing a space set on a first surface of the bracket for accommodating the sensor, and providing a second surface that is opposite to the first surface for bonding with the wafer-level lens.

2. The WLO module of claim 1, wherein the sensor comprises an image sensor.

3. The WLO module of claim 1, wherein the wafer-level lens comprises a microlens.

4. The WLO module of claim 1, wherein the bracket has a width larger than a width of the sensor, such that the sensor is bonded with the wafer-level lens via the bracket.

5. The WLO module of claim 1, wherein the sensor comprises an active array that is not located at a center of the sensor.

6. The WLO module of claim 5, wherein the bracket has an asymmetrical shape such that, when the sensor is bonded with the first surface of the bracket, a center of the active array of the sensor substantially coincide with an optical axis of the wafer-level lens.

7. The WLO module of claim 1, wherein a distance between the first surface and. the second surface of the bracket determines focusing between the sensor and. the wafer-level lens.

8. The WLO module of claim 1, further comprising an infra-read (IR) filter interposed, between the bracket and the wafer-level lens for blocking incoming infra-red light.

9. The WLO module of claim 1, further comprising a lens barrel for holding the wafer-level lens.

10. A method of assembling a wafer-level optics (WLO) module, comprising:
providing a sensor configured to convert an optical image into an electronic signal;
providing at least one wafer-level lens;
accommodating the sensor in a space set on a first surface of a bracket; and
bonding a second surface of the bracket with the wafer-level lens, the second surface being opposite to the first surface.

11. The method of claim 10, wherein the sensor comprises an image sensor.

12. The method of claim 10, wherein the wafer-level lens comprises a microlens.

13. The method of claim 10, wherein the bracket has a width larger than a width of the sensor, such that the sensor is bonded with the wafer-level lens via the bracket.

14. The method of claim 10, wherein the sensor comprises an active array that is not located at a center of the sensor.

15. The method of claim 14, wherein the bracket has an asymmetrical shape such that, when the sensor is bonded with the first surface of the bracket, a center of the active array of the sensor substantially coincide with an optical axis of the wafer-level lens.

16. The method of claim 10, wherein a distance between the first surface and the second surface of the bracket determines focusing between the sensor and the wafer-level lens.

17. The method of claim 10, further comprising a step of interposing an infra-read (IR) filter between the bracket and the wafer-level lens for blocking incoming infra-red light.

18. The method of claim 10, further comprising a step of holding the wafer-level lens by a lens barrel.
